(19) United States
(12) Patent Application Publication
(10) Pub. No.: US 2004/0264246 A1
(43) Pub. Date: Dec. 30, 2004

(54) Nonvolatile semiconductor memory

(76) Inventors: Koji Sakui, Tokyo (JP); Riichiro Shirota, Fujisawa-shi (JP); Fumitaka Arai, Yokohama-shi (JP); Masayuki Ichige, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/832,381

(22) Filed: Apr. 27, 2004

(30) Foreign Application Priority Data
Apr. 28, 2003 (JP) 2003-124317

(51) Int. Cl. G11C 16/04

(52) U.S. Cl. 365/185.01

(57) ABSTRACT

A gate insulation film is formed on a semiconductor substrate. A floating gate is formed on the gate insulation film. The floating gate have a substantially triangular cross section that is taken along a plane extending parallel to a first direction on the semiconductor substrate and perpendicular to the semiconductor substrate and have a bottom that contacts the gate insulation film and two sloping sides that extend upwards from the ends of the bottom. A pair of control gates is contacted an inter-gate insulation film formed on the two sloping sides of the floating gate. The floating gate is adapted to be driven by capacitive coupling with the pair of control gates.

### CROSS-REFERENCE TO RELATED APPLICATIONS

This application is based upon and claims the benefit of priority from prior Japanese Patent Application No. 2003-124317, filed Apr. 28, 2003, the entire contents of which are incorporated herein by reference.

### BACKGROUND OF THE INVENTION

1. Field of the Invention

This invention relates to a nonvolatile semiconductor memory having a multilayer gate structure including a floating gate and a control gate.

2. Description of the Related Art

FIGS. 1 through 3 illustrates a known NAND type EEPROM realized by utilizing shallow trench isolation (STI). FIG. 1 is a schematic plan view and FIGS. 2 and 3 are two different cross-sectional views of FIG. 1.

As shown in FIG. 2, a gate insulation film GI, which is a tunneling insulation film, is formed on a silicon substrate (Si-sub) and floating gates FG are formed thereon. The floating gates FG of adjacent cells are separated and electrically insulated from each other. The structure that separates adjacently located floating gates FG apart from each other is referred to as a slit. The floating gates FG between a pair of slits are covered at the top and the opposite lateral sides by an inter-gate insulation film IGI. Each floating gate FG can be made to hold an electric charge for a long period because it is covered by a tunneling insulation film and an inter-gate insulation film.

A control gate CG is formed on the inter-gate insulation film. Normally, a control gate CG is shared by a large number of cell transistors and adapted to drive the number of cell transistors simultaneously. The control gate CG is also referred to as word line WL.

On the other hand, the cross-sectional view of FIG. 3 is taken along a bit line BL. Stacked gate structures illustrated in FIG. 2 are arranged on the substrate in rows along the direction of bit lines BL as seen from FIG. 3. Each cell transistor is processed in a self-aligning manner by means of resist or a processing mask layer. In a NAND type memory where a number of cells are connected in series by way of select gates, adjacent cells share a source and a drain in order to reduce the area occupied by each cell. Each word line WL and the gap separating adjacent word lines WL are formed with minimum feature size by micro-processing.

Electrons are injected into a floating gate FG by applying a high write potential to the corresponding control gate CG and grounding the substrate. As cell transistors are micronized, an increased parasitic capacitance appears between adjacent cells and between a floating gate FG and a peripheral structure. For this reason, there is a tendency of raising the write voltage of cell transistors for the purpose of increasing the data writing rate. Control gates CG need to be reliably insulated from each other and word line drive circuits are required to withstand high voltages when a high voltage is used for the write voltage. This poses a problem when arranging memory elements at high density and driving them to operate at high speed.

It is possible to roughly estimate the potential required for write operation by seeing the structure shown in FIGS. 1 and 3. The control gate CG and the floating gate FG and the floating gate FG and the substrate can be regarded as capacitors where the gate insulation film and the tunneling insulation film are respectively sandwiched. In other words, as seen from the control gate CG, the memory cell is equivalent to a structure where two capacitors are connected in series.

FIG. 4 is an equivalent circuit diagram of a cell that is obtained when the capacitance of the capacitor between the control gate CG and the floating gate FG is Cip and the capacitance of the capacitor between the floating gate FG and the substrate is Ctox. The electric potential Vfg of the floating gate FG when a high write potential (Vpgm=Vcg) is applied to the control gate CG is defined by Cip and Ctox and can be roughly estimated by using the formula below:

Vfg=Cr×(Vcg−Vt+Vt0),

where Cr=Cip/(Cip+Ctox) and Vt represents the threshold voltage of the cell transistor while Vto represents the threshold voltage (neutral threshold voltage) when the floating gate FG is totally free from electric charge.

The higher the electric potential Vfg of the floating gate FG, the stronger the electric field applied to the tunneling insulation film so injection of electrons into the floating gate FG can easily take place. It will be appreciated from the above formula that the value of Vfg can be raised by increasing the capacitance ratio (Cr) provided that Vcg is held to a constant level. In other words, it is necessary to make Cip have a large value relative to Ctox in order to reduce the write voltage.

The capacitance of a capacitor is proportional to the dielectric constant of the thin film arranged between the electrodes and the area of the opposed electrodes and inversely proportional to the distance between the opposed electrodes. A write/erase operation is obstructed when a leak current flows through the tunneling insulation film for allowing an electric charge to pass through for the purpose of the write/erase operation. Therefore, a technique of increasing the contact area of the gate insulation film and the floating gate FG and that of the gate insulation film and the control gate CG is normally used to increase the value of Cip. Techniques such as increasing the top surface of the floating gate FG by reducing the width of the slit (dimension A in FIG. 2) and increasing the length of the lateral walls of the floating gate FG (dimension B in FIG. 2) by increasing the film thickness of the floating gate FG have been developed to date.

However, when such a technique is used, the slit needs to be extremely micronized relative to the dimensions of the gate and the wiring materials and the difficulty of forming the gate increases as the floating gate FG is made thicker. Additionally, the parasitic capacitance between FG-FG increases as a result of micronization. In short, it obstructs micronization of cell transistors to maintain the capacitance ratio.

It is conceivable to reduce the write voltage by modifying the configuration of the floating gate FG and the control gate CG.

As a matter of fact, Japanese Laid-Open Patent (Kokai) No. 11-145429 describes a NAND type EEPROM that is designed to allow write/erase/read operations to be performed with a low voltage by increasing the capacitance between booster plates.

Japanese Laid-Open Patent (Kokai) No. 2002-217318 describes a nonvolatile memory device including micronized elements that are realized by raising the coupling ratio of the floating gate and the control gate and thereby reducing the write voltage.

Japanese Laid-Open Patent (Kokai) No. 2002-50703 describes a nonvolatile semiconductor memory device including MOSFETs that show improved write/erase/read characteristics and area realized by forming floating gate at opposite lateral sides of each control gate.

Furthermore, Y. Sasago et al. “10-MB/s Multi-Level Programming of Gb-Scale Flash Memory Enabled by New AG-AND Cell Technology” 2002 IEEE IEDM, pp. 952-954 describes an AG-AND memory cell where an assist gate is arranged adjacent to a floating gate.

However, it is still difficult to increase the capacitance between the control gate and the floating gate by means of the above described prior art. In other words, it is difficult to reduce the write voltage and realize a highly integrated memory that operates at high speed by means of the prior art. Therefore, a nonvolatile semiconductor memory that can reduce the write voltage, has high capacity and realize a high speed operation.

### BRIEF SUMMARY OF THE INVENTION

According to an aspect of the present invention, there is provided a nonvolatile semiconductor memory comprises a memory cell having a floating gate and a pair of control gates, the floating gate being formed on a gate insulation film formed on a semiconductor substrate, the floating gate having a cross section that is taken along a plane extending parallel to a first direction on the semiconductor substrate and perpendicular to the semiconductor substrate and having a bottom that contacts the gate insulation film and two sloping sides that extend upwards from the ends of the bottom, and the pair of control gates contacting an inter-gate insulation film formed on the two sloping sides of the floating gate, the floating gate is adapted to be driven by capacitive coupling with the pair of control gates.

According to another aspect of the present invention, there is provided a nonvolatile semiconductor memory comprises a memory cell column having a plurality of memory cells, each having a floating gate and a control gate and adapted to electric data rewriting, a first selection transistor connected to an end of the memory cell column, a bit line connected to the other end of the first selection transistor, a sense amplifier circuit connected to the bit line and having a latch feature, a second selection transistor connected to the other end of the memory cell column, a source line connected to the other end of the second selection transistor, a source line drive circuit that drives the source line, and a control gate drive circuit that drives the control gates of the plurality of memory cells, the floating gates of the plurality of memory cells being arranged cyclically in a first direction on a surface of a semiconductor substrate, each floating gate having a cross section that is taken along a plane extending parallel to the first direction and perpendicular to the semiconductor substrate and having a bottom and two sloping sides that extend upwards from the ends of the bottom, and a pair of control gates contacting an inter-gate insulation film formed on the two sloping sides of each floating gate.

### BRIEF DESCRIPTION OF THE SEVERAL VIEWS OF THE DRAWING

FIG. 1 shows a schematic plan view of a known nonvolatile semiconductor memory;

FIG. 2 shows a schematic cross-sectional view of FIG. 1;

FIG. 3 shows a schematic cross-sectional view of FIG. 1 different from FIG. 2;

FIG. 4 shows a circuit diagram of an equivalent circuit of FIG. 1;

FIG. 5 shows a schematic plan view of part of cell array of the first embodiment of a nonvolatile semiconductor memory;

FIG. 6 shows a schematic cross-sectional view of the cell array of FIG. 5;

FIG. 7 shows a schematic cross-sectional view of the cell array of FIG. 5, different from FIG. 6;

FIG. 8 shows a circuit diagram of an equivalent circuit of a cell of the first embodiment;

FIG. 9 shows a schematic cross-sectional view of part of the first embodiment of the nonvolatile semiconductor memory, illustrating the first step of the manufacturing method;

FIG. 10 shows a schematic cross-sectional view illustrating the step next to that of FIG. 9;

FIG. 11 shows a schematic cross-sectional view illustrating the step next to that of FIG. 10;

FIG. 12 shows a schematic cross-sectional view of part of the nonvolatile semiconductor memory obtained, which is the first modified embodiment of the first embodiment;

FIG. 13 shows a schematic cross-sectional view of part of the nonvolatile semiconductor memory obtained, which is the second modified embodiment of the first embodiment;

FIG. 14 shows a schematic cross-sectional view of part of the nonvolatile semiconductor memory obtained, which is the third modified embodiment of the first embodiment;

FIG. 15 shows a schematic cross-sectional view of cell array of the second embodiment of the nonvolatile semiconductor memory;

FIG. 16 shows a circuit diagram of an equivalent circuit of a cell array of FIG. 15;

FIG. 17 shows a schematic cross-sectional view of cell array of the third embodiment of the nonvolatile semiconductor memory;

FIG. 18 shows a circuit diagram of an equivalent circuit of a cell array of FIG. 17;

FIG. 19 shows a schematic cross-sectional view of cell array of the fourth embodiment of the nonvolatile semiconductor memory;

FIG. 20 shows a circuit diagram of a known NAND type EEPROM;

FIG. 21 shows a schematic illustration of an example combination of electric potentials that can be used when writing data to a NAND type EEPROM as shown in FIG. 20;

FIG. 22 shows a schematic illustration of an example combination of electric potentials that are applied respectively to related parts when writing data to the second embodiment of the nonvolatile semiconductor memory;

FIG. 23 shows a circuit diagram of an equivalent circuit of the cell indicated in FIG. 22, schematically illustrating the first example combination of selected electric potentials that can be used when writing data to the cell;

FIG. 24 shows a circuit diagram of an equivalent circuit of the cell indicated in FIG. 22, schematically illustrating the second example combination of selected electric potentials that can be used when writing data to the cell;

FIG. 25 shows a schematic illustration of an example of data write operation using the combination of electric potentials shown in FIG. 24;

FIG. 26 shows a schematic illustration of an example combination of electric potentials that are applied respectively to related parts when erasing data from the second embodiment of the nonvolatile semiconductor memory;

FIG. 27 shows a schematic illustration of an example combination of electric potentials that are applied respectively to related parts when reading data from the second embodiment of the nonvolatile semiconductor memory; and

FIG. 28 shows a circuit diagram of the memory cell array of the fifth embodiment of the nonvolatile semiconductor memory.

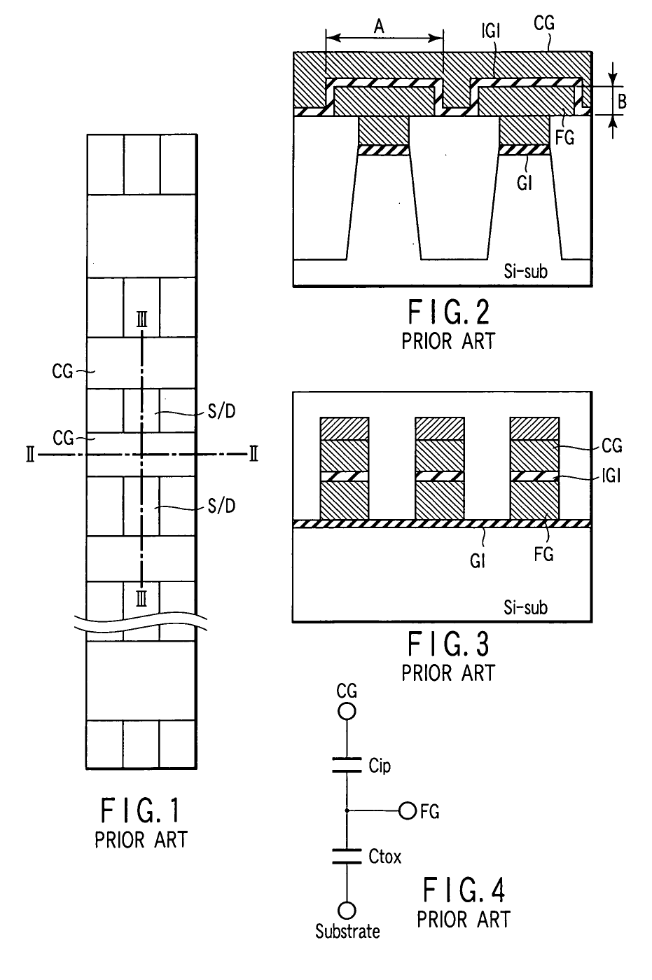

### DETAILED DESCRIPTION OF THE INVENTION

Now, embodiments of the present invention will be described in greater detail.

(1st Embodiment)

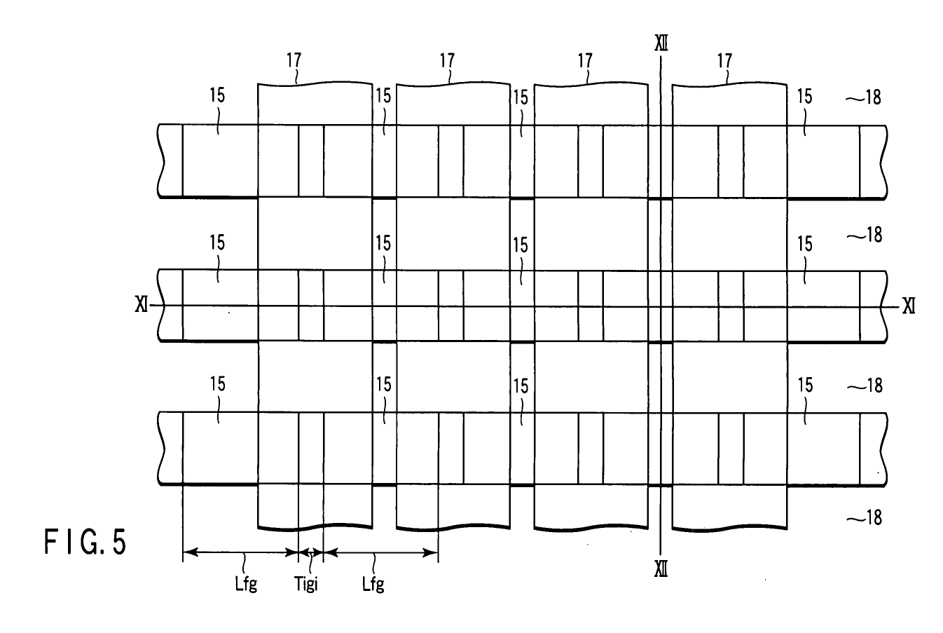

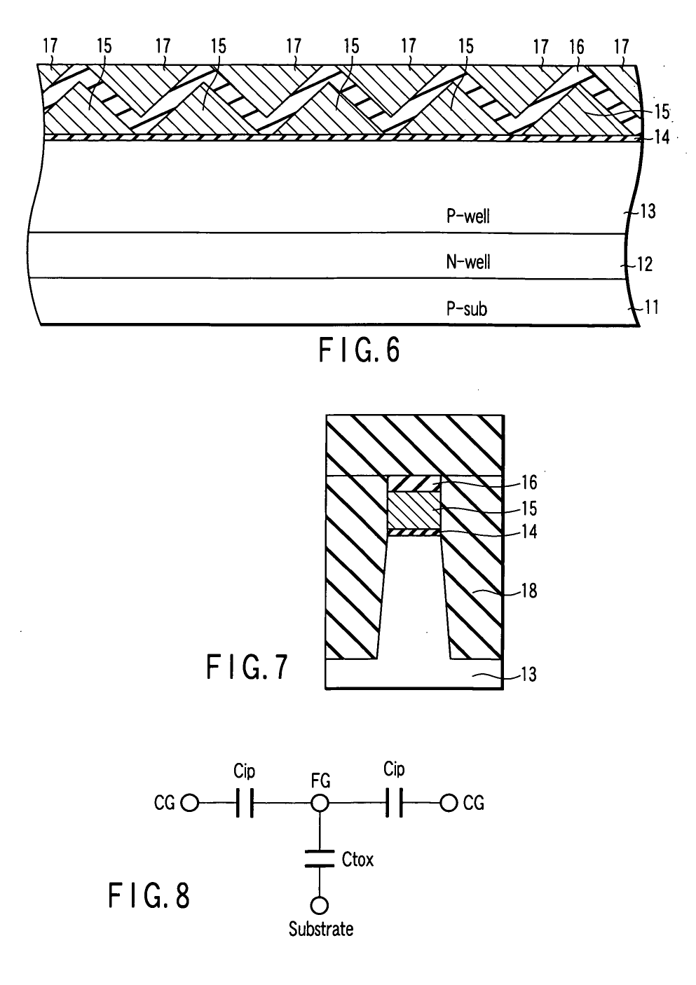

FIGS. 5 through 7 schematically illustrate part of the cell array of the first embodiment of a nonvolatile semiconductor memory. FIG. 5 is a schematic plan view of part of the cell array. FIGS. 6 and 7 are schematic cross-sectional views taken along different lines in FIG. 5.

An N-type well (N-well) 12 is formed on a P-type silicon semiconductor substrate (P-sub) 11. P-type well (P-well) 13 is formed on the N-type well 12. A plurality of trenches for shallow trench isolation (STI) are formed in the P-type well 13. An insulation film is buried in the trenches to form STI layers 18.

A plurality of floating gates 15 are formed and arranged at a predetermined pitch on each of the surfaces of the P-type well 13 that are electrically insulated from each other by STI layers 18 with a gate insulation film 14 which is, for example a silicon oxide film, interposed between them. The gate insulation film 14 is either a single silicon nitride layer or a layer having a multilayer structure and containing silicon nitride. As shown in FIG. 5, the plurality of floating gates 15 are arranged cyclically in a direction (first direction) extending parallel to the corresponding STI layer 18. As shown in the cross-sectional view of FIG. 6 taken vertically relative to the surface of the P-type well 13 along a line extending in the first direction, each of the floating gates 15 shows a substantially triangular cross-section, having a bottom line that is held in contact with the gate insulation film 14 and runs parallel to the semiconductor substrate and a pair of oppositely disposed slopes that extend upward respectively from the opposite ends of the bottom line.

Further, an inter-gate insulation film 16 is formed on the floating gates 15. The inter-gate insulation film 16 is either a single layer film which may be, for example, a silicon oxide film, a silicon nitride film, an aluminum (Al) oxide film, a hafnium oxide film or a zirconium oxide film or a multilayer film which may be, for example, by arranging a silicon oxide film and a silicon nitride film (ONO film). The inter-gate insulation film 16 has a thickness greater than the gate insulation film 14.

Additionally, a control gate 17 that operates as word line WL is buried between any two adjacently located pairs of floating gates 15. The control gates 17 are arranged at a predetermined pitch and extend in a direction perpendicular to the STI layers 18 as shown in FIG. 5.

As shown in FIG. 7, any two adjacently located floating gates 15 are electrically insulated by an STI layer 18 that is an insulator buried in a trench formed in the semiconductor substrate.

More specifically, take a single floating gate 15. A pair of control gates 17, 17 are formed on the two slopes of the floating gate 15 with an inter-gate insulation film 16 interposed between them and held in contact with the slopes of the gate 15. As shown in the cross-sectional view of FIG. 6 taken vertically relative to the surface of the P-type well along a line extending in the first direction, each of the control gates 17 has a downwardly projecting inverted triangular profile having a top surface extending parallel to the surface of the P-type well and a pair of oppositely disposed slopes that extend downward from respective opposite edges of the top surface.

The floating gates 15 and the control gates 17 are formed by, for example, a polycrystalline silicon film into which an impurity is injected to reduce the electric resistance.

Assume here that the pitch at which the floating gates 15 or the control gates 17 are arranged is 2F and the length of the surface of each floating gate 15 that is held in contact with the gate insulation film 14 or the gate length that corresponds to the length of the bottom of the floating gate 15 is Lfg.

The floating gates 15 and the control gates 17 are arranged with the inter-gate insulation film 16 interposed between them. Between any two adjacently located floating gates 15 or control gates 17 need to be separated from each other by a distance greater than the thickness (Tigi) of the inter-gate insulation film 16 in order to avoid any breakdown of each of the gates. Thus, Lfg is selected so as to satisfy the following relationship.

F<Lfg<2F−Tigi

It will be appreciated that the gate length Lfg of each floating gate 15 of this embodiment can take a value as large as possible. As a result, it is not necessary to form a diffusion layer, which becomes a source/drain region, at the opposite edges of a channel formed on the surface of the P-type well 13 located below the floating gate 15, i.e., at each part of the P-type well 13 located below a control gate 17 and corresponds to an area where no floating gate 15 is arranged and the inter-gate insulation film 16 contacts the gate insulation film 14 shown in FIG. 6. In other words, each cell can be formed only in a semiconductor region showing the same conductivity type. In short, in the first embodiment, each part of the P-type well 13 located below the control gate 17 and also below the floating gate 15 is entirely a semiconductor region showing the same conductivity type.

Since no diffusion layer that shows the conductivity type opposite to that of the P-type well 13 is formed in the P-type well 13, it is possible to completely avoid the influence of the short channel effect that poses a serious problem to micronization of transistors.

In conventional cells, each floating gate is driven by a control gate. To conversely, in the cells of the first embodiment, a floating gate 15 is driven by a pair of control gates 17 that are located at opposite sides thereof. Thus, as seen from the equivalent circuit of FIG. 8, the effective capacitance between the control gates CG and the floating gate FG is the sum of Cip and Cip which is greater than a conventional cell so that it is possible to reduce the write voltage. Note that, in FIG. 8, Ctox represents the capacitance between the floating gate FG and the substrate.

It will be appreciated from above that each cell of the first embodiment can secure a sufficiently large capacitance ratio. As a result, the capacitance ratio can be increased if the gate length and channel width of the cell transistor is reduced so that the write voltage can be reduced.

For instance, a gate length as large as about 90 nm can be used in the 55 nm generation in terms of design rule.

The control gate 17 is buried in the space between two adjacently located floating gates 15. Therefore, capacitive coupling of any two floating gates 15 that are adjacently located in the direction of word lines is prevented from taking place.

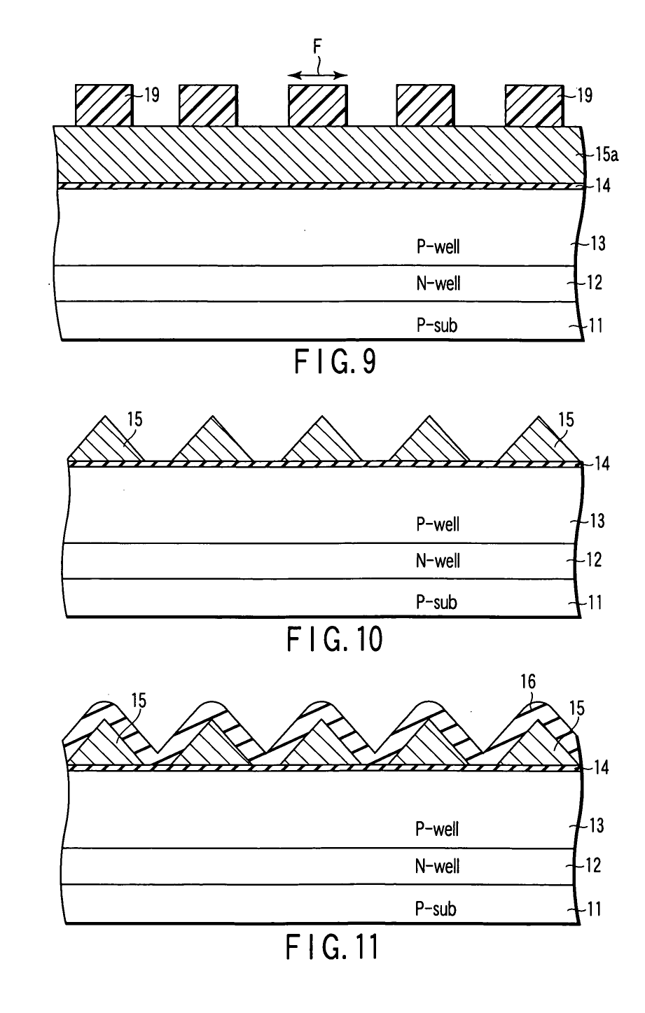

FIGS. 9 through 11 illustrates different steps of the method of manufacturing the nonvolatile semiconductor memory of the first embodiment.

As shown in FIG. 9, an N-type well 12 is formed on a P-type silicon semiconductor substrate 11 and a P-type well 13 is formed on the N-type well 12. Then, a gate insulation film 14 is formed on the P-type well 13. Subsequently, a polycrystalline silicon film 15a is deposited on the gate insulation film 14 in order to form floating gates 15 and an etching mask layer 19 is formed thereon. The etching mask layer 19 has a repetitive pattern of lines/spaces and the smallest pitch F conforming to the design rule is used for the arrangement of lines/spaces.

Then, a number of floating gates 15 having a substantially triangular cross section as shown in FIG. 10 are formed in rows as the polycrystalline silicon film 15a is selectively etched by means of an anisotropic etching technique.

Thereafter, an inter-gate insulation film 16 is deposited on the entire surface as shown in FIG. 11 and then a polycrystalline silicon film is deposited also on the entire surface to form control gates. A number of control gates 17 are produced as shown in FIGS. 5 and 6 as the polycrystalline silicon film is flatten by the chemical mechanical polishing (CMP) step.

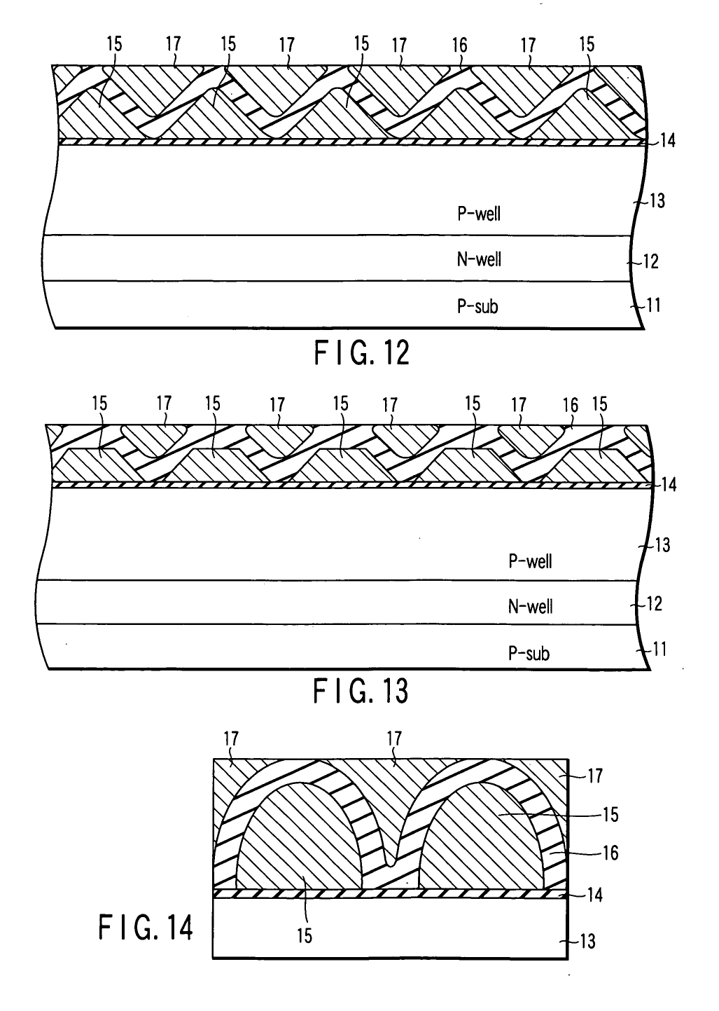

The floating gates 15 may be made to show a different cross section to produce a modified embodiment such as the first modified embodiment as shown in FIG. 12 or the second modified embodiment as shown in FIG. 13 by appropriately selecting the profile of the mask layer 19 used in step shown in FIG. 9, the type of etching gas that is used in the anisotropic etching step shown in FIG. 10, the etching conditions and so on.

For example, in the case of the first modified embodiment of the nonvolatile semiconductor memory as shown in FIG. 12, the floating gates 15 show a substantially triangular cross section with a rounded apex.

On the other hand, in the case of the second modified embodiment of the nonvolatile semiconductor memory as shown in FIG. 13, the floating gates 15 show a trapezoidal cross section and have no apex. In other words, the cross section of each floating gate 15 has a bottom line that runs parallel to the surface of the semiconductor substrate, a top line that is arranged vis-á-vis and runs parallel to the bottom line and tow slope lines connecting the top line and the bottom line.

The two slope lines of the floating gate 15 may be straight lines or curved lines.

FIG. 14 shows a schematic cross-sectional view of part of the third modified embodiment of the nonvolatile semiconductor memory, where the two slope lines are curved lines whose angle of inclination linearly increases as a function of the height from the semiconductor substrate provided that the angle of inclination of each of the curved lines is defined as the angle formed by the tangent at a given height from the surface of the semiconductor substrate and the surface of the semiconductor substrate and a linear increase is defined by a function whose value only increases and does not decrease relative to a variable and hence that does not show any point of inflection. The angle of inclination is always not greater than 90 degrees.

The modified embodiment of FIG. 14 may be referred to as a variant to the embodiment of FIG. 13 where the floating gates 15 show a substantially trapezoidal cross section.

(2nd Embodiment)

The cell array of the first embodiment shown in FIGS. 5 through 7 are connected to bit lines and source lines by way of selection gate transistors in an actual circuit arrangement.

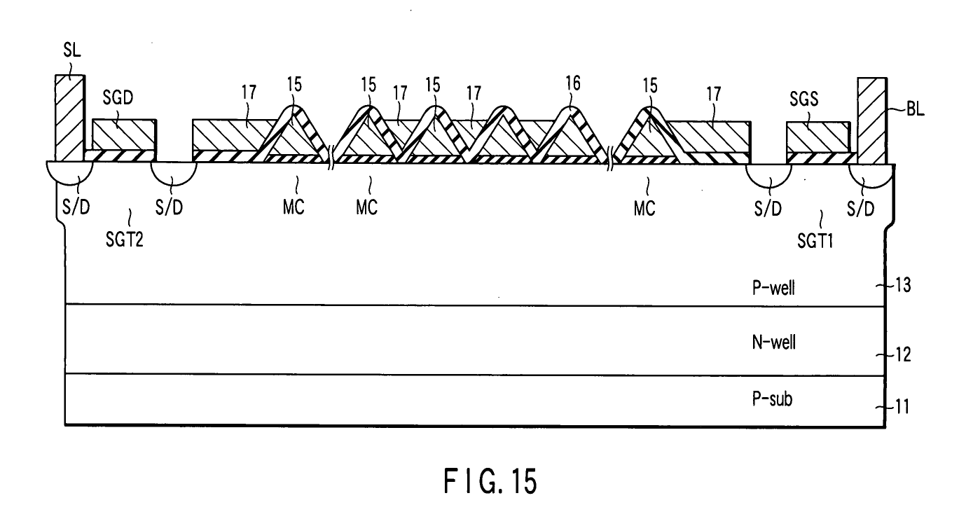

FIG. 15 is a schematic cross-sectional view of the cell array of the second embodiment of the nonvolatile semiconductor memory. The illustrated cell array comprises a plurality of memory cells connected in series and a pair of selection gates. In FIG. 15, the components that correspond to those of FIG. 6 are denoted respectively by the same reference symbols and will not be described any further.

In the cell array of FIG. 15, the selection gate transistor SGT1 arranged at the bit line BL side comprises a pair of N-type diffusion layers S/D that operate as source/drain regions and a selection gate SGS. The bit line BL contacts one of the pair of diffusion layers S/D. The selection gate transistor SGT2 that is arranged at the source line SL side comprises a pair of diffusion layers S/D that operate as source/drain regions and a selection gate SGD. The source line SL contacts one of the pair of diffusion layers S/D. As pointed out above, no diffusion layer S/D that operates as source/drain region is formed in each cell.

An insulation film same as that of the inter-gate insulation film 16 formed between each combination of a floating gate 15 and a control gate 17 that are arranged adjacently is also used for the gate insulation films arranged respectively under the selection gates SGS, SGD of the selection gate transistors SGT1, SGT2.

In the cell array of FIG. 15, the selection gates SGS, SGD are separated respectively from the control gate 17 at the bit line side and the control gate 17 at the source line side of the cells MC. As pointed out above, no diffusion layer S/D that operates as source/drain region is formed in each cell.

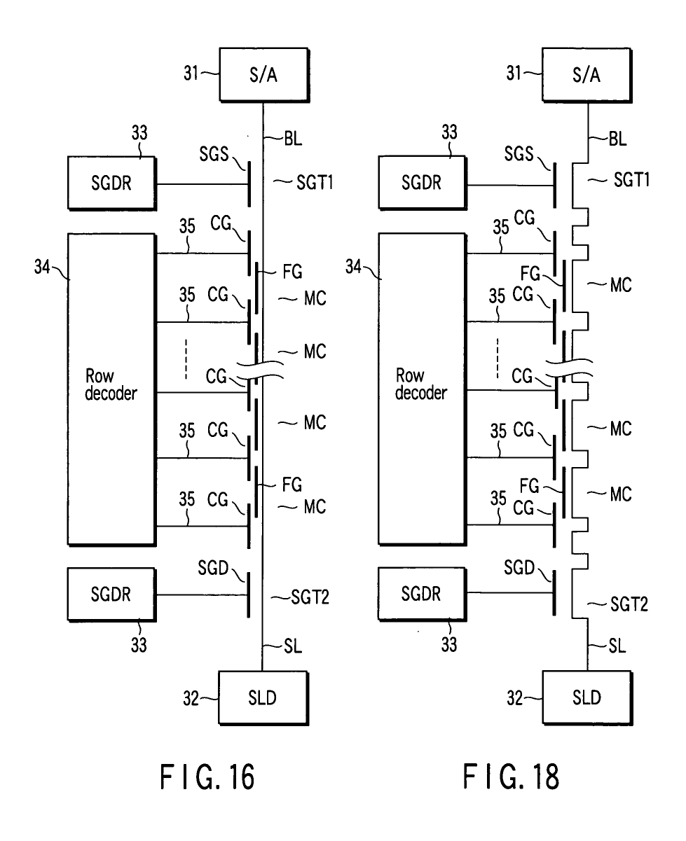

FIG. 16 is a circuit diagram of an equivalent circuit of a cell array of FIG. 15. In FIG. 16, CG denotes a control gate and FG denotes a floating gate of memory cell.

A sense amplifier circuit (S/A) 31 having a latch feature is connected to the bit line BL. A source line drive circuit (SLD) 32 is connected to the source line SL so as to drive the source line SL by applying any of various voltages to it. Selection gate drive circuits (SGDR) 33 are connected respectively to the selection gates SGS, SGD of the selection gate transistors SGT1, SGT2 so as to drive the respective selection gates SGS, SGD. A row decoder 34 is connected to the control gates CG of the memory cells by way of respective wires 35 that are made of tungsten, aluminum or copper so as to operate as control gate drive circuit that drives the control gates CG.

(3rd Embodiment)

FIG. 17 is a schematic cross-sectional view of the cell array of the third embodiment of the nonvolatile semiconductor memory. The illustrated cell array comprises a plurality of memory cells and a pair of selection gates. In FIG. 17, the components that correspond to those of FIG. 15 are denoted respectively by the same reference symbols and will not be described any further.

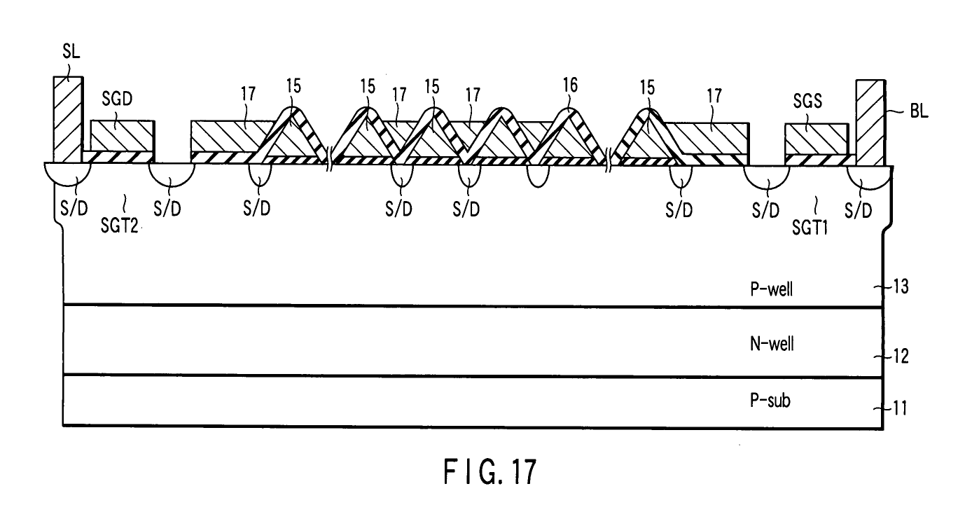

In the instance of FIG. 15, no diffusion layer that operates as source/drain region is formed in the substrate at the opposite side of each floating gate 15 of the memory cell MC in each cell array as pointed out above. Conversely, in the instance of FIG. 17, an N-type diffusion layer S/D that operates as source/drain region is formed in the substrate at the opposite side of each floating gate 15. FIG. 18 is a circuit diagram of an equivalent circuit of a cell array of FIG. 17.

(4th Embodiment)

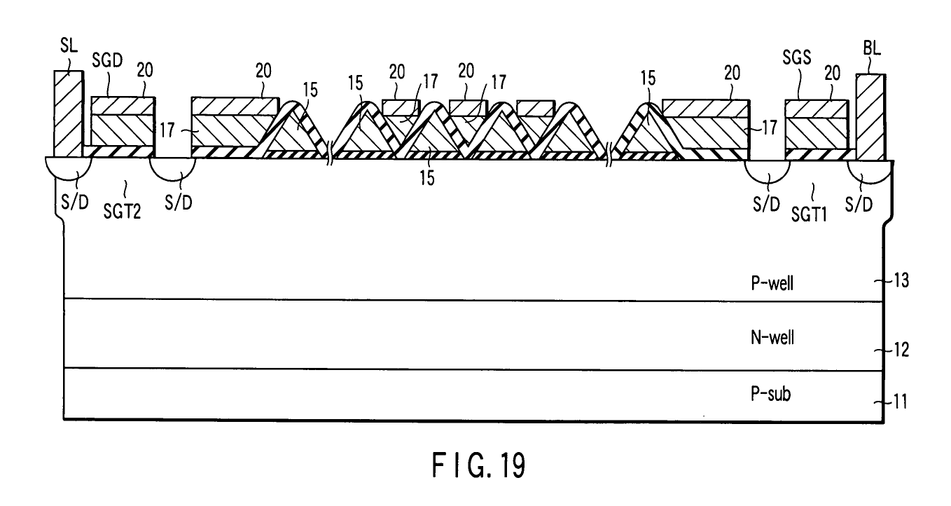

FIG. 19 is a schematic cross-sectional view of the cell array of the fourth embodiment of nonvolatile semiconductor memory. The illustrated cell array comprises a plurality of memory cells and a pair of selection gates. In FIG. 19, the components that correspond to those of FIG. 15 are denoted respectively by the same reference symbols and will not be described any further.

In the cell array of FIG. 19, each control gate 17 of memory cell MC has a saliside structure. A saliside structure can be formed typically in a manner as described below. Referring to FIG. 19, a metal film of titanium, cobalt, nickel or the like is formed on the control gates 17 and the selection gates SGS, SGD. Subsequently, the control gates 17 and the selection gates SGS, SGD are made to have a siliside structure as the metal film is subjected to a heat treatment step to produce siliside of the metal, or a siliside film 20.

In this embodiment, it is possible to reduce the resistance of each of the control gates 17 of the memory cells MC and the selection gates SGS, SGD.

Now, the operation of the second through fourth embodiments of nonvolatile semiconductor memory will be described below.

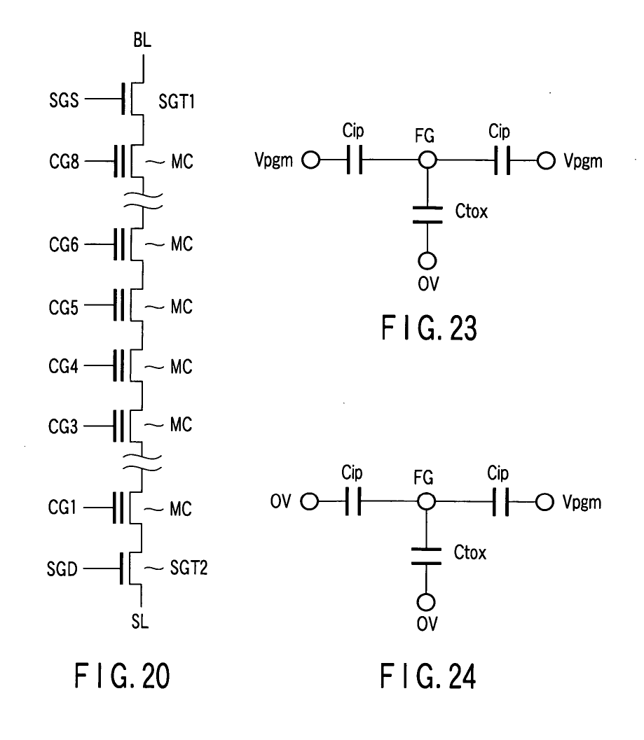

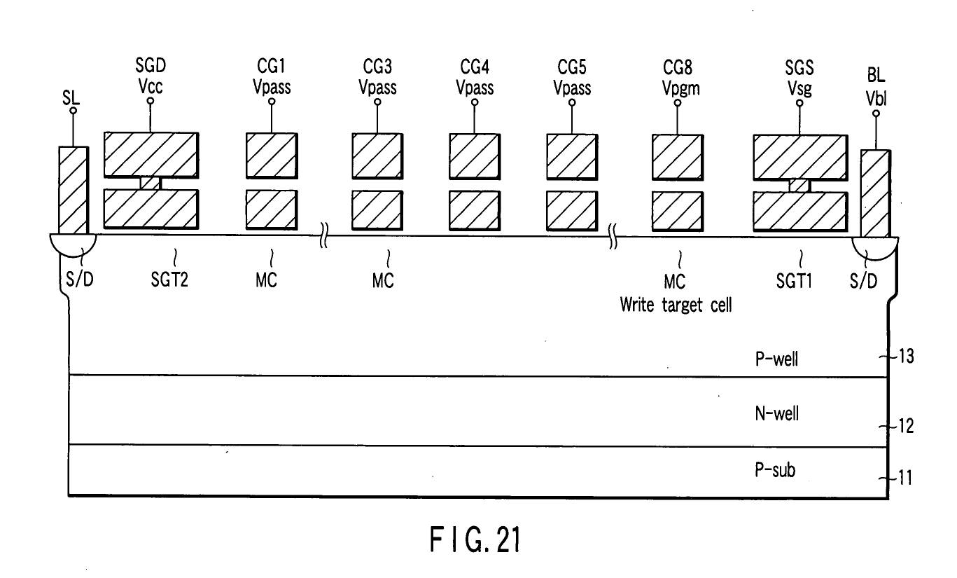

Firstly, the operation of a known NAND type EEPROM will be discussed by referring to FIGS. 20 and 21. FIG. 20 is a circuit diagram of a known NAND type EEPROM, illustrating the circuit configuration. FIG. 21 is a schematic illustration of an example combination of electric potentials that can be used when writing data to a NAND type EEPROM shown in FIG. 20. In FIGS. 20 and 21, the same components are denoted respectively by the same reference symbols.

The NAND type EEPROM is formed by connecting the sources/drains of the plurality of cell transistors that are arranged side by side to operate as so many memory cells and the selection gates SGT1, SGT2 in series. The selection gate SGT1 is connected to the bit line BL, while the selection gate SGT2 is connected to the source line SL.

When writing data, a predetermined gate potential Vsg is applied to the selection gate SGS at the side of the bit line BL. A sufficiently low potential Vbl is supplied to the bit line BL. A potential level that is sufficiently high for make the selection gate SGT1 ON relative to Vbl is selected for the gate potential Vsg. As Vbl is supplied to the bit line, the selection gate SGT1 becomes ON and Vbl is transferred to the selected cell transistor so that the channel potential of the selected cell transistor sufficiently falls to allow a write operation to be carried out there.

In the illustrated known EEPROM, both the operation of writing data to a cell by applying write potential Vpgm to the selected word line WL (CG8 in FIG. 21) and the operation of applying transfer potential Vpass to the non-selected word lines WL (other than CG8 in FIG. 21) to form a channel utilize the capacitive coupling of the control gate and the floating gate.

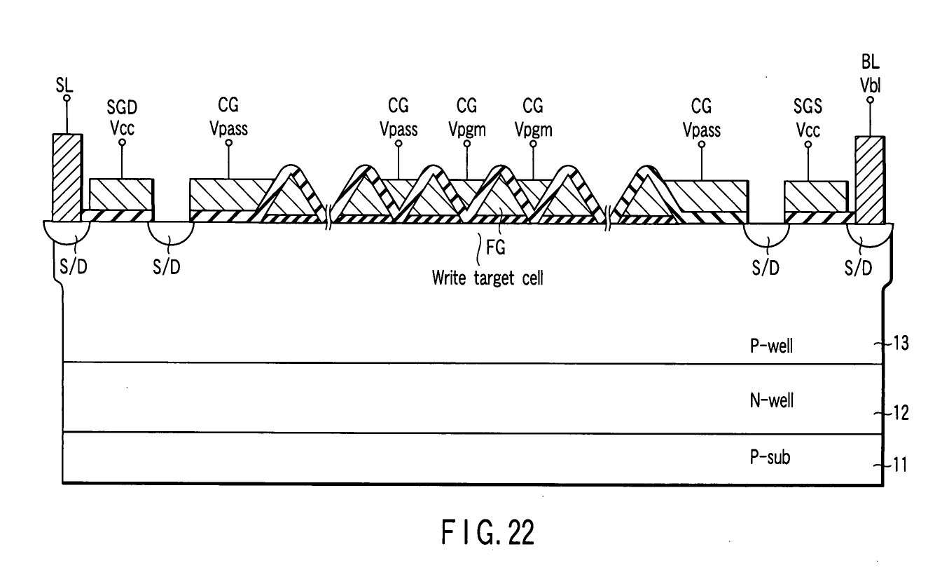

FIG. 22 is a schematic illustration of an example combination of electric potentials that are applied respectively to related parts when writing data to the second embodiment of nonvolatile semiconductor memory.

As described above, a floating gate FG has a pair of control gates CG and a floating gate FG is selected by means of a pair of control gates CG. In other words, a floating gate FG is driven by a capacitive coupling with a pair of control gates CG.

For a write operation, the same write voltage Vpgm is applied to the two control gates CG arranged adjacent to the floating gate FG to which a data is written and the substrate (P-type well 13) is held typically to 0V. FIG. 23 is a circuit diagram of an equivalent circuit of a cell where such a write operation is conducted. In the illustrated state, an electric charge is injected from the substrate to the floating gate FG.

As described above by referring to the first embodiment, it is possible to raise the capacitance ratio regardless of micronization of elements and hence Vpgm can be reduced from its counterpart of the prior art.

The potentials applied to the selection gates SGD, SGS and the potential applied to each of the control gates CG are generated respectively by the selection gate drive circuits 33 and the row decoder 34. The potential applied to the source line SL is generated by the source line drive circuit 32. The sense amplifier circuit 31 is connected to the bit line BL. The sense amplifier circuit 31 applies a predetermined voltage to the bit line BL for a data reading operation and latches the read out data.

Application of the same voltage to a pair of control gates CG to drive a single floating gate FG for a write operation is described above. However, it is also possible to apply different voltages respectively to a pair of control gates CG.

FIG. 24 is a circuit diagram of an equivalent circuit of a cell where such a write operation is conducted. In this case, Vpgm is supplied to one of the pair of control gates CG while 0V is supplied to the other control gate CG. In FIG. 24, the capacitance ratio of Cip and Ctox is assumed to be 1.5:1 and the neutral threshold voltage for a condition where no electric charge is injected to the floating gate FG and the current threshold voltage are assumed to be 0V. In the case of FIG. 23, the electric potential Vfg of the floating gate FG is obtained by the formula below.

$$\begin{matrix}Vfg = Vpgm \times 2 \times Cip / ( 2 \times Cip + Ctox ) \\ = 0.75 \times Vpgm\end{matrix}$$

On the other hand, in the case of FIG. 24, the electric potential Vfg of the floating gate FG is obtained by the formula

$$\begin{matrix}Vfg = Vpgm \times Cip / ( 2 \times Cip + Ctox ) \\ = 0.375 \times Vpgm\end{matrix}$$

Thus, it is possible to significantly reduce the capacitance ratio by changing the electric potential of one of the pair of control gates CG.

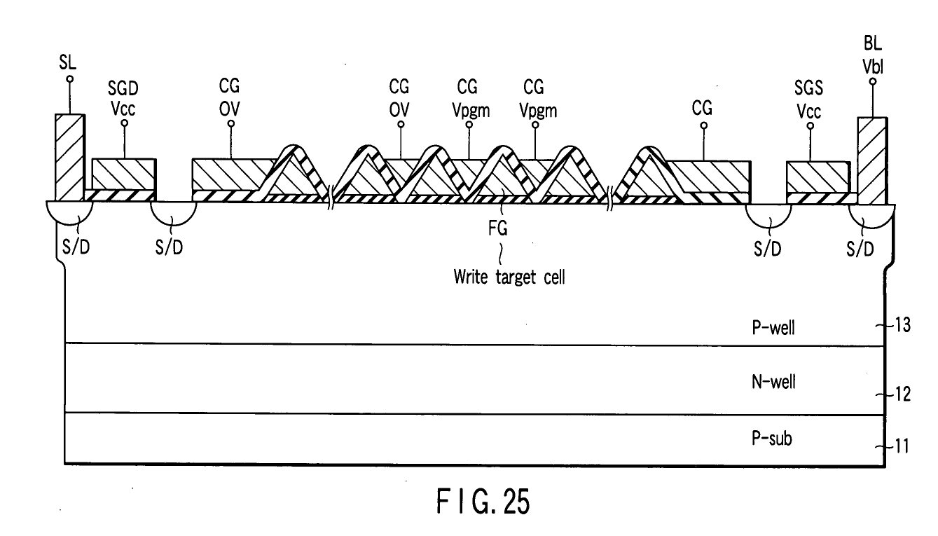

FIG. 25 is an example of data write operation using the above characteristics. Referring to FIG. 25, Vpgm is applied to the control gates CG at the opposite sides of the cell (target cell) where the write operation is conducted. Using the above described assumption, 0.75×Vpgm is applied to the floating gate FG of the write target cell. On the other hand, 0V is applied to one of the pair of control gates CG of the cell located adjacently to the left of the write target cell, while Vpgm is applied to the other control gate CG. Thus, a potential of 0.375×Vpgm is applied to the floating gate FG of the cell located adjacently to the left of the write target cell. Therefore, the field stress of the adjacent cell is ½ of the floating gate FG of the selected cell, which is sufficient for suppressing any write error. Potential Vpass predetermined for potential transfer or for the purpose of raising the channel potential is applied to the control gates CG remote from that cell. For the operation of an actual device, an appropriate combination of electric potentials is prepared for the control gates CG by considering the write characteristics, the channel voltage rising characteristics, the potential transfer characteristics and so on of the device.

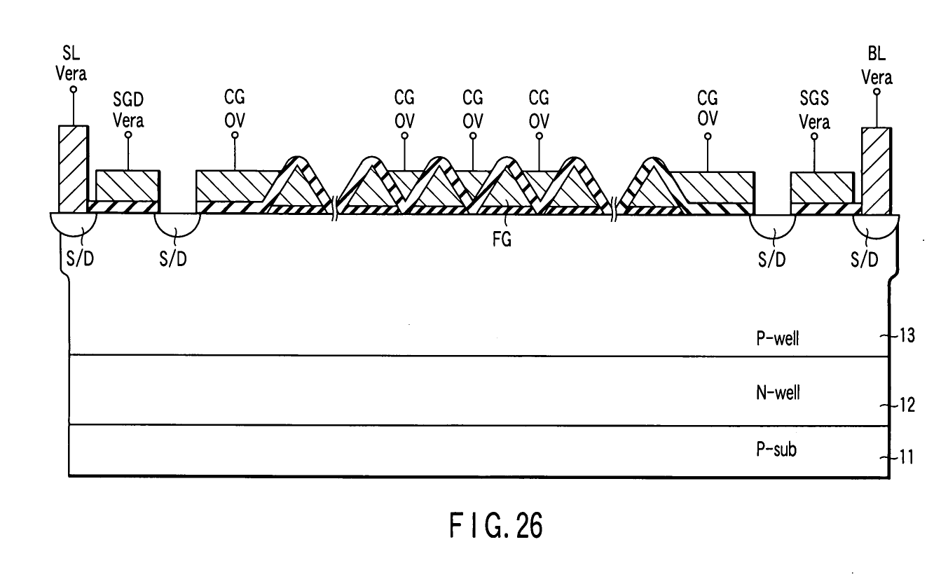

FIG. 26 is a schematic illustration of an example combination of electric potentials that are applied respectively to related parts when erasing a data from the second embodiment of the nonvolatile semiconductor memory.

When erasing the data of a cell, the electric potential of the substrate (P-type well 13) where the memory cell is formed is raised to an erase potential Vera. At the same time, the potentials of the diffusion layers S/D and the selection gates SGS, SGD that are connected respectively to the bit line BL and the source line SL are raised to the potential Vera of the substrate in order to prevent breakdown. Additionally, a sufficiently low potential such as 0V is supplied to the control gates CG of the cells adjacent to the cell where the erase operation is conducted. Then, the electric charge of the floating gate FG is drawn out to the substrate whose electric potential is raised to consequently erase the data.

The data of the cells where no erase operation is conducted are prevented from being erased by keeping the potential of the control gates CG of those cells floating because the potential of the control gates CG are raised to the potential of the substrate by capacitive coupling of the control gates CG and the substrate.

In this way, data can be reliably erased from a memory having a cell structure where two control gates CG are arranged respectively at opposite sides of each floating gate FG.

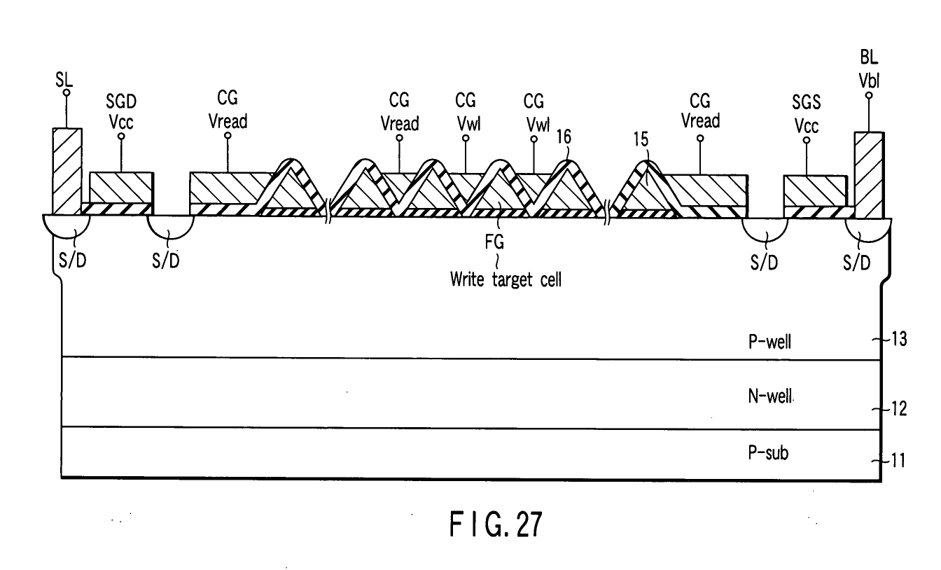

FIG. 27 is a schematic illustration of an example combination of electric potentials that are applied respectively to related parts when reading data from the second embodiment of nonvolatile semiconductor memory.

Referring to FIG. 27, for a read operation, read voltage Vwl is supplied to the pair of control gates CG of the floating gate FG of the cell where a read operation is conducted. It is desirable that an appropriate electric potential level is selected for the read voltage Vwl by considering the write characteristics, the data retention characteristics and the operational range of the threshold voltage of the cell transistors and so on. If the read voltage is assumed to be Vwl=0V, a potential of 0V is applied to the floating gate FG of the cell (target cell) to which data is read.

On the other hand, potential Vread is applied to the control gates CG located adjacent relative to the control gates CG of the read target cell. It is desirable that an appropriate electric potential level is selected for Vread so as to be able to determine the threshold voltage of the read target cell, eliminating the influence of the non-selected cells that are connected to the read target cell.

Note that above-mentioned sense amplifier circuit 31 having a latch feature is connected to the bit line BL so that the threshold voltage of the read target cell is determined and the data of the read target cell is sensed by the sense amplifier circuit 31. Note that it is so arranged that, in the write operation, the threshold voltage of only the cell whose pair of control gates CG arranged at opposite sides of the cell are made to show the read voltage Vwl is determined and all the cells whose pair of control gates CG show a combination different from the above one are held to the ON sate regardless of the data stored therein.

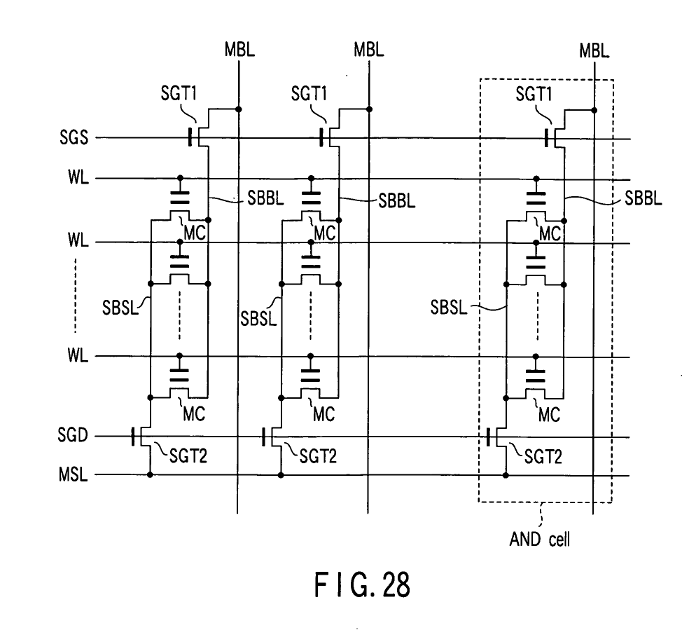

It will be appreciated that the present invention is by no means limited to the above described embodiments, which may be modified in various different ways without departing from the scope of the present invention. For example, a plurality of memory cells are connected in series to realize a NAND type memory in the description given above by referring to FIG. 15 or 17, a plurality of memory cells may alternatively be connected in a manner as shown in FIG. 28 to realize an AND type memory.

In the nonvolatile semiconductor memory illustrated in FIG. 28, each AND type memory cell unit has a sub bit line SBBL and a sub source line SBSL and a plurality of memory cells MC are connected in parallel between the sub bit line SBBL and the sub source line SBSL.

The sub bit line SBBL is connected to a main bit line MBL by way of a selection gate transistor SGT1. The sub source line SBSL is connected to a main source line MSL by way of a selection gate transistor SGT2.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor memory comprising:
a memory cell having a floating gate and a pair of control gates, the floating gate being formed on a gate insulation film formed on a semiconductor substrate, the floating gate having a cross section that is taken along a plane extending parallel to a first direction on the semiconductor substrate and perpendicular to the semiconductor substrate and having a bottom that contacts the gate insulation film and two sloping sides that extend upwards from the ends of the bottom, and the pair of control gates contacting an inter-gate insulation film formed on the two sloping sides of the floating gate,
wherein the floating gate is adapted to be driven by capacitive coupling with the pair of control gates.

2. A nonvolatile semiconductor memory according to claim 1, wherein the floating gate having a substantially triangular cross section.

3. A nonvolatile semiconductor memory according to claim 1, wherein the floating gate having a substantially trapezoidal cross section.

4. A nonvolatile semiconductor memory according to claim 1, wherein the two sloping sides have substantially straight lines.

5. A nonvolatile semiconductor memory according to claim 1, wherein the two sloping sides are formed respectively by curved lines whose angle of inclination linearly increase as a function of the height from the semiconductor substrate provided that the angle of inclination of each of the curved lines is defined as the angle formed by the tangent at a given height from the surface of the semiconductor substrate and the surface of the semiconductor substrate.

6. A nonvolatile semiconductor memory according to claim 5, wherein the angle of inclination is not greater than 90 degrees.

7. A nonvolatile semiconductor memory according to claim 1, further comprising a diffusion layer of the opposite conductivity type to the semiconductor substrate, the diffusion layer being formed in the surface regions located below the control gate and not located below the floating gate.

8. A nonvolatile semiconductor memory according to claim 1, wherein all the regions of the semiconductor substrate located below the control gate and those located below the floating gate are semiconductor regions of the same conductivity type.

9. A nonvolatile semiconductor memory according to claim 1, wherein the inter-gate insulation film is a single layer film which is a silicon oxide film, a silicon nitride film, an aluminum oxide film, a hafnium oxide film or a zirconium oxide film or a multilayer film.

10. A nonvolatile semiconductor memory according to claim 1, wherein the inter-gate insulation film has a film thickness greater than the gate insulation film.

11. A nonvolatile semiconductor memory according to claim 1, wherein the gate insulation film is either a single silicon nitride layer or a layer having a multilayer structure and containing silicon nitride.

12. A nonvolatile semiconductor memory according to claim 1, wherein each of the floating gate and the control gate is formed by a polycrystalline silicon film.

13. A nonvolatile semiconductor memory according to claim 1, wherein the control gate has a saliside structure of titanium, cobalt or nickel.

14. A nonvolatile semiconductor memory according to claim 1, wherein the control gate is connected to a wiring made of tungsten, aluminum or copper.

15. A nonvolatile semiconductor memory comprising:
a memory cell column having a plurality of memory cells, each having a floating gate and a control gate and adapted to electric data rewriting;
a first selection transistor connected to an end of the memory cell column;
a bit line connected to the other end of the first selection transistor;
a sense amplifier circuit connected to the bit line and having a latch feature;
a second selection transistor connected to the other end of the memory cell column;
a source line connected to the other end of the second selection transistor;
a source line drive circuit that drives the source line; and
a control gate drive circuit that drives the control gates of the plurality of memory cells;
wherein the floating gates of the plurality of memory cells being arranged cyclically in a first direction on a surface of a semiconductor substrate, each floating gate having a cross section that is taken along a plane extending parallel to the first direction and perpendicular to the semiconductor substrate and having a bottom and two sloping sides that extend upwards from the ends of the bottom, and a pair of control gates contacting an inter-gate insulation film formed on the two sloping sides of each floating gate.

16. A nonvolatile semiconductor memory according to claim 15, wherein the floating gate having a substantially triangular cross section.

17. A nonvolatile semiconductor memory according to claim 15, wherein the floating gate having a substantially trapezoidal cross section.

18. A nonvolatile semiconductor memory according to claim 15, wherein the two sloping sides have substantially straight lines.

19. A nonvolatile semiconductor memory according to claim 15, wherein the two sloping sides are formed respectively by curved lines whose angle of inclination linearly increase as a function of the height from the semiconductor substrate provided that the angle of inclination of each of the curved lines is defined as the angle formed by the tangent at a given height from the surface of the semiconductor substrate and the surface of the semiconductor substrate.

20. A nonvolatile semiconductor memory according to claim 19, wherein the angle of inclination is not greater than 90 degrees.

21. A nonvolatile semiconductor memory according to claim 15, wherein the floating gates are electrically insulated by an insulator buried in the trenches formed in the semiconductor substrate.

22. A nonvolatile semiconductor memory according to claim 15, wherein the arrangement of the floating gates is defined by
F<Lfg<2F−Tigi,
where F is a half of the pitch of arrangement of the floating gates or the control gates, Lfg is the gate length of the floating gates and Tigi is the film thickness of the inter-gate insulation film.

23. A nonvolatile semiconductor memory according to claim 15, further comprising a diffusion layer of the opposite conductivity type to the semiconductor substrate, the diffusion layer being formed in the surface regions located below the control gate and not located below the floating gate.

24. A nonvolatile semiconductor memory according to claim 15, wherein all the regions of the semiconductor substrate located below the control gate and those located below the floating gate are semiconductor regions of the same conductivity type.

25. A nonvolatile semiconductor memory according to claim 15, wherein the inter-gate insulation film is a single layer film which is a silicon oxide film, a silicon nitride film, an aluminum oxide film, a hafnium oxide film or a zirconium oxide film or a multilayer film.

26. A nonvolatile semiconductor memory according to claim 15, wherein the inter-gate insulation film has a film thickness greater than the gate insulation film.

27. A nonvolatile semiconductor memory according to claim 15, wherein the gate insulation film is either a single silicon nitride layer or a layer having a multilayer structure and containing silicon nitride.

28. A nonvolatile semiconductor memory according to claim 15, wherein each of the floating gate and the control gate is formed by a polycrystalline silicon film.

29. A nonvolatile semiconductor memory according to claim 15, wherein the control gate has a saliside structure of titanium, cobalt or nickel.

30. A nonvolatile semiconductor memory according to claim 15, wherein the control gate is connected to a wiring made of tungsten, aluminum or copper.

31. A nonvolatile semiconductor memory according to claim 15, wherein the plurality of memory cells having N memory cells which are connected in series and (N+1) control gates are provided in the memory cell column.

32. A nonvolatile semiconductor memory according to claim 15, wherein the plurality of memory cells are arranged to form an AND type.

33. A nonvolatile semiconductor memory comprising:
a pair of floating gates, formed on a gate insulation film formed on a semiconductor substrate and arranged in a first direction on the same plane on the semiconductor substrate, each floating gate having a cross section that is taken along a plane extending parallel to the first direction and perpendicular to the semiconductor substrate and having a bottom and two sloping sides that extend upwards from the ends of the bottom; and
a control gate formed to bury between the pair of floating gates in a self-aligning manner with an inter-gate insulation film interposed between them.

34. A nonvolatile semiconductor memory according to claim 33, wherein the floating gate having a substantially triangular cross section.

35. A nonvolatile semiconductor memory according to claim 33, wherein the floating gate having a substantially trapezoidal cross section.

36. A nonvolatile semiconductor memory according to claim 33, wherein the two sloping sides have substantially straight lines.

37. A nonvolatile semiconductor memory according to claim 33, wherein the two sloping sides are formed respectively by curved lines whose angle of inclination linearly increase as a function of the height from the semiconductor substrate provided that the angle of inclination of each of the curved lines is defined as the angle formed by the tangent at a given height from the surface of the semiconductor substrate and the surface of the semiconductor substrate.

38. A nonvolatile semiconductor memory according to claim 37, wherein the angle of inclination is not greater than 90 degrees.

39. A nonvolatile semiconductor memory according to claim 33, wherein the floating gates are electrically insulated by an insulator buried in the trenches formed in the semiconductor substrate.

40. A nonvolatile semiconductor memory according to claim 33, further comprising a diffusion layer of the opposite conductivity type to the semiconductor substrate, the diffusion layer being formed in the surface regions located below the control gate and not located below the floating gate.

41. A nonvolatile semiconductor memory according to claim 33, wherein all the regions of the semiconductor substrate located below the control gate and those located below the floating gate are semiconductor regions of the same conductivity type.

42. A nonvolatile semiconductor memory according to claim 33, wherein the inter-gate insulation film is a single layer film which is a silicon oxide film, a silicon nitride film, an aluminum oxide film, a hafnium oxide film or a zirconium oxide film or a multilayer film.

43. A nonvolatile semiconductor memory according to claim 33, wherein the inter-gate insulation film has a film thickness greater than the gate insulation film.

44. A nonvolatile semiconductor memory according to claim 33, wherein the gate insulation film is either a single silicon nitride layer or a layer having a multilayer structure and containing silicon nitride.

45. A nonvolatile semiconductor memory according to claim 33, wherein each of the floating gate and the control gate is formed by a polycrystalline silicon film.

46. A nonvolatile semiconductor memory according to claim 33, wherein the control gate has a saliside structure of titanium, cobalt or nickel.

47. A nonvolatile semiconductor memory according to claim 33, wherein the control gate is connected to a wiring made of tungsten, aluminum or copper.
